(19) United States
(12) Patent Application Publication
(10) Pub. No.: US 2025/0180986 A1
(43) Pub. Date: Jun. 5, 2025

(54) MULTI-LEVEL OPTICAL STRUCTURES

(71) Applicant: NIL Technology ApS, Kongens Lyngby (DK)

(72) Inventor: Maksim Zalkovskij, Copenhagen (DK)

(21) Appl. No.: 18/839,095

(22) PCT Filed: Feb. 28, 2023
(86) PCT No.: PCT/EP2023/055006

§ 371 Date: Aug. 16, 2024

Related U.S. Application Data
(60) Provisional application No. 63/316,182, filed on Mar. 3, 2022.

(51) Int. Cl. G03F 7/00; G02B 5/18; G03F 1/60

(52) U.S. Cl. CPC G03F 7/0002; G02B 5/1852; G02B 5/1857; G03F 1/60

(57) ABSTRACT

The present disclosure describes optical structures and methods for manufacturing the optical structures. In some implementations, a method includes imprinting a multi-level structured surface of a tool into an imprint material that is disposed on a substrate so that the imprint material is imprinted with a multi-level structure corresponding to the multi-level structured surface of the tool. The substrate includes sublayers disposed on a support, and the sublayers are disposed one atop another and include an optical sublayer on the support, a first hard mask sublayer on the optical sublayer, a spacer sublayer on the first hard mask sublayer, and a second hard mask sublayer on the spacer sublayer. Etching operations subsequently are performed to cause the imprinted multi-level structure to be transferred into the optical sublayer of the substrate.

### FIELD OF THE DISCLOSURE

The present disclosure relates to optical structures.

### BACKGROUND

A tool (e.g., a mold) can be used to imprint a multi-level pattern into a layer on a substrate in which optical elements are to be formed. Such tools can be used, for example, as part of a mass production manufacturing process. Manufacturing the optical elements may take place in some instances at a wafer-level in which tens, hundreds, or even thousands of optical elements are formed in parallel using the same tool.

### SUMMARY

The present disclosure describes multi-level optical structures and methods of fabricating such multi-level optical structures. The techniques include using a tool that has a multi-level structured surface that corresponds, for example, to a pixel layout design for optical elements, and that is transferred by imprinting to an imprint material on a substrate. Various etching operations then can be performed to cause the imprinted pattern to be transferred into an optical sublayer in the substrate.

In one aspect, for example, the present disclosure describes a method that includes imprinting a multi-level structured surface of a tool into an imprint material that is disposed on a substrate so that the imprint material is imprinted with a multi-level structure corresponding to the multi-level structured surface of the tool. The substrate includes sublayers disposed on a support. The sublayers are disposed one atop another and include an optical sublayer on the support, a first hard mask sublayer on the optical sublayer, a spacer sublayer on the first hard mask sublayer, and a second hard mask sublayer on the spacer sublayer. The method further includes subsequently performing etching operations to cause the imprinted multi-level structure to be transferred into the optical sublayer of the substrate.

Some implementations include one or more of the following features. For example, in some implementations, the multi-level structured surface of the tool corresponds to a pixel layout design for optical elements. The optical elements can include, for example, at least one of diffractive optical elements of meta optical elements.

In some implementations, the optical sublayer is composed of amorphous silicon, crystalline silicon, silicon nitride, titanium oxide, aluminum zinc oxide, a niobium oxide (e.g., NbO, NbO₂ or Nb₂O₅) or zinc oxide. The support may be composed, for example, of glass. In some instances, each of the hard mask sublayers is composed of a metal. For example, at least one of the hard mask sublayers can be composed of chrome, aluminum or titanium. In some instances, the spacer sublayer is composed of silicon dioxide. In some cases, the imprint material is a resist.

In some implementations, each of the etching operations is a selective etch. For example, in some implementations, performing the etching operations includes performing the following etches sequentially: a first etch to remove a residual layer of the imprint material; a second etch to remove exposed portions of the second hard mask sublayer; a third etch to remove exposed portions of the spacer sublayer; a fourth etch to remove exposed portions of the first hard mask sublayer; a fifth etch to remove, at least partially, exposed portions of the optical sublayer; a sixth etch to remove a remainder of the imprint material and exposed portions of the spacer sublayer; a seventh etch to remove a remainder of the second hard mask sublayer and exposed portions of the first hard mask sublayer; an eighth etch to remove exposed portions of the optical sublayer; a ninth etch to remove a remainder of the spacer sublayer; and a tenth etch to remove a remainder of the first hard mask sublayer.

In some instances, the multi-level structured surface of the tool is imprinted into the imprint material by nanoimprint lithography. In some cases, the third etch also reduces a height of the imprint material. In some implementations, at least one of the etch operations is an inductively coupled plasma (ICP) etch.

In some implementations, the multi-level structure imprinted into the imprint material and transferred into the optical sublayer of the substrate includes at least three different levels.

Various advantages may be provided by some implementations. For example, in some implementations, the multi-level structured surface of the tool is transferred to the optical sublayer of the substrate through a process that uses only a single imprint.

Other aspects, features and advantages will be readily apparent from the following detailed description, the accompanying drawings and the claims.

### BRIEF DESCRIPTION OF THE DRAWINGS

FIG. 1 is a flow chart of a method in accordance with this disclosure.

FIG. 2 illustrates a cross-sectional view showing an example of an imprinted layer on a substrate.

FIG. 3 illustrates an example sequence of etching operations for transferring the multi-level structure in the imprinted layer of FIG. 2 to an optical sublayer of the substrate.

FIGS. 4 through 13 illustrate example details of the etching operations of FIG. 3 in some implementations.

FIG. 14A is a cross-sectional view of a multi-level optical structure.

FIG. 14B is a top view of the multi-level optical structure of FIG. 14A.

FIG. 15A is a cross-sectional view of a multi-level optical structure.

FIG. 15B is a top view of the multi-level optical structure of FIG. 15A.

FIG. 16 illustrates examples of dimensions of multi-level optical structure.

FIG. 17 illustrates further examples of multi-level optical structures.

FIG. 18 illustrates an example of single channel module that includes an optical element having a multi-level structure.

FIG. 19 illustrates an example of multi-channel module that includes an optical element having a multi-level structure.

### DETAILED DESCRIPTION

The present disclosure describes techniques for fabricating multi-level optical structures that include optical elements such as meta optical elements (MOEs) or diffractive optical elements (DOEs). MOEs, for example, can include a metasurface having a distributed array of meta-atoms (e.g., nanostructures). The meta-atoms may, individually or collectively, interact with light waves. For example, the nanostructures or other meta-atoms may change a local amplitude, a local phase, or both, of an incoming light wave.

In accordance with some implementations, a multi-level tool (e.g., a mold) can be used to imprint a multi-level structure into a layer on a substrate in which the optical elements are to be formed. The tool can include a multi-level structured surface that corresponds to the pixel layout design for the multi-level optical elements and that can be transferred (e.g., by imprinting) to an imprint material on a substrate. The multi-level tool can be used, for example, as part of a mass production manufacturing process. Manufacturing the optical elements may take place in some instances at a wafer-level in which tens, hundreds, or even thousands of optical elements are formed in parallel using the same tool.

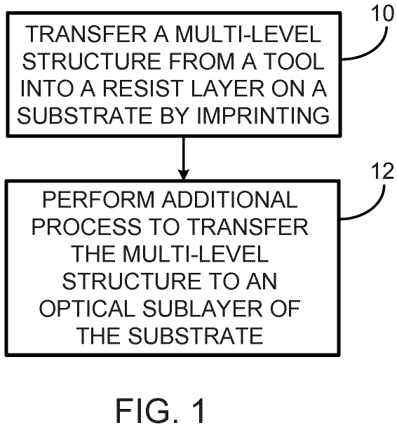

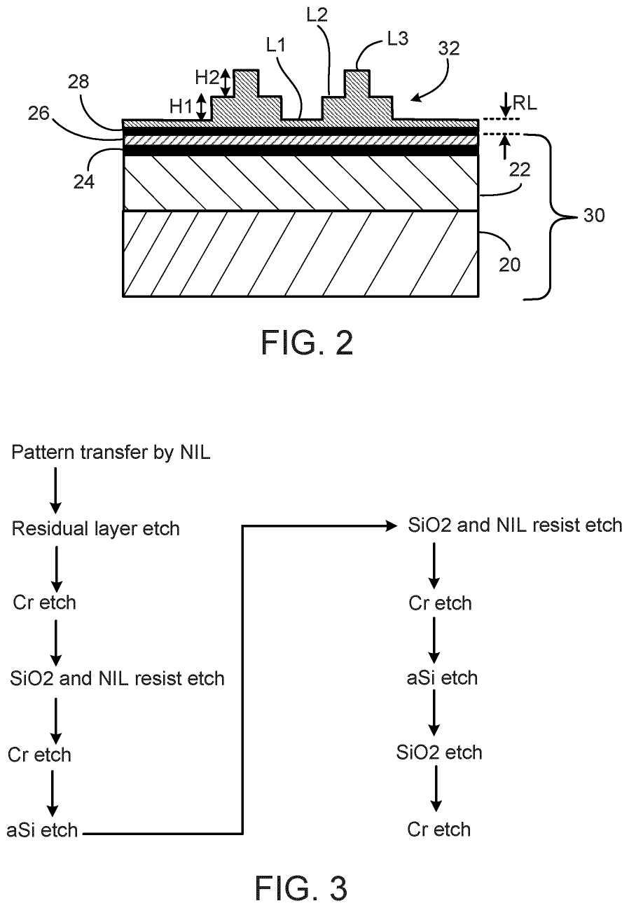

As indicated by 10 in FIG. 1, the techniques can include using the tool to transfer the multi-level pattern in the surface of the tool to an imprint layer on a substrate, for example, by nanoimprint lithography (NIL). In general, the multi-level pattern imprinted into the imprint layer will be a negative of the multi-level pattern in the surface of the tool. As illustrated by FIG. 2, the substrate 30 includes several sublayers, including an optical sublayer 22 on a glass or other support 20 that is substantially transparent to a particular wavelength or range of wavelengths (e.g., 940 nm or a range of ranges in the infra-red part of the electromagnetic spectrum).

As a result of additional processing, including various etching operations, the multi-level structure is transferred (12 in FIG. 1) from the imprinted layer to the optical sublayer 22 on the glass or other support 20. In some instances, the lateral dimensions of the multi-level structure can be transferred to the optical sublayer 22 by the etching operations with only a little, if any, change in those dimensions. On the other hand, the vertical dimensions of the multi-level structure formed in the optical sublayer 22 may depend, for example, on the respective initial thicknesses of the various sublayers of the substrate 30 as well as the etch times and etch rates for the sublayers.

The optical sublayer 22 can be selected to have particular optical properties such that the optical elements formed therein by the resulting multi-level structure have specified optical characteristics and optical functionality at the operating wavelength(s).

As further shown in FIG. 2, the substrate 30 further includes first and second hard mask (e.g., metal) sublayers 24, 28 separated from one another by a spacer sublayer 26. The hard mask sublayers 24, 28, as well as the intervening spacer sublayer 26, can be disposed, one atop the other, directly over the optical sublayer 22. The imprint layer 32, into which the multi-level structure of the tool is imprinted, is disposed on the second hard mask layer 28 that is further from the optical sublayer 22.

In some implementations, the support 20 can be, for example, a glass substrate having a thickness in the range of 0.5 mm-2.0 mm, a glass surface roughness Ra of less than 2 nm, and a scratch/dig ratio of 60/20. Optical sublayer 22 can be composed, for example, of silicon (e.g., amorphous, poly-crystalline, or crystalline silicon) with a thickness of in the range of 300 nm-2000 nm, and a surface roughness Ra of less than 2 nm. In some instances, the optical sublayer 22 has optical properties (at 940 nm) as follows: n=3.5±0.05, and k=6×10⁻⁵±4×10⁻⁵. The optical properties of the sublayer 22 may differ in other implementations. For example, in some cases, the refractive index n is in the range 3.4-3.9, and k<10⁻³. Each of the hard mask sublayers 24, 28 can be composed, for example, of a metal (e.g., chrome (Cr)) having a thickness in the range of 5 nm-50 nm. The hard mask chrome sublayers 24, 28 can be deposited, for example by e-beam evaporation or sputtering. The intervening spacer sublayer 26 can be composed, for example, of SiO₂ having a thickness in the range of 5 nm-100 nm.

The foregoing materials, thicknesses and/or optical properties of the sublayers of the substrate 30, as well as deposition techniques, are examples. Thus, different materials, thicknesses and/or optical properties, as well as other deposition techniques, can be used in some implementations. For example, in some implementations, the optical sublayer 22 may be composed of silicon nitride (SiNₓ) or Titanium oxide (TiO₂), and/or the hard mask sublayers 24, 28 may be composed of aluminum (Al) or titanium (Ti). In general, the hard mask sublayers 24, 28 and the spacer sublayer 26 should be chosen to allow for selective etching of the substrate's sublayers in a controlled manner.

In some implementations the imprint layer 32 is a UV-curable, microwave-curable, and/or thermally-curable epoxy or resin (e.g., a photoresist). As shown in the example of FIG. 2, the multi-level pattern structure imprinted into the imprint layer 32 results in three-different levels, L1, L2, L3. That is, various features in the imprinted structure are at a respective one of the levels. In the illustrated example, after the imprinting, there is a residual layer (e.g., of resist) having a thickness (RL) of about 50-70 nm. In this example, the second level L2 has a height (H1) of about 90 nm, and the third level L3 has a height (H2) of about 90 nm. These values may differ for some implementations. Further, although the foregoing example describes a multi-level structure having three levels (and two plateaus), more generally the imprinting technique can be used to create multi-level patterns having N levels (and N−1 plateaus), where N has a value of at least three. Thus, in some instances, the imprinting technique can be used to create multi-level patterns having four, five, six or more levels.

As explained above, after transferring the pattern, by imprinting, to the imprint layer 32, various etching operations are performed, with the result that the multi-level pattern is transferred to the optical sublayer 22 on the glass or other support 20. In a particular example, explained in greater detail below, the process includes at least ten etching operations (see FIG. 3). Other implementations, however, may include a different number of etches, different types of etches, and/or etches that are performed in a different order. Further, other details of the etches described below may differ in some implementations.

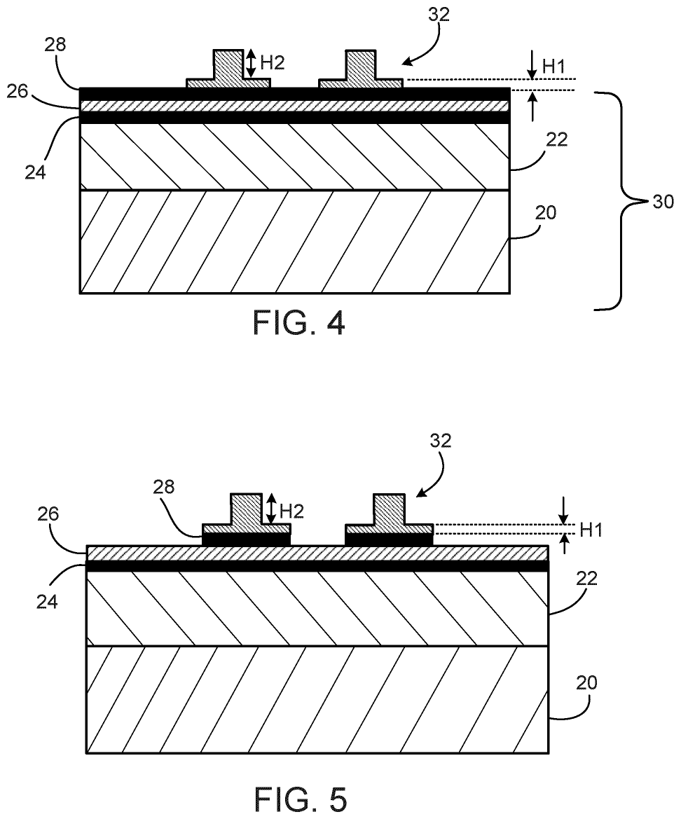

A first etch is performed to remove the residual layer of the imprint material (e.g., the resist) 32. The result of this etch, according to an example implementation, is illustrated in FIG. 4, which shows a first plateau at a height (H1) of about 40 nm, and a second plateau at a height (H2) of about 90 nm. That is, the height of the resist pattern is reduced by about 50±5 nm during this first etch. In some instances, this etch can be achieved by using an inductively coupled plasma (ICP).

Next, a second etch is performed to remove the exposed portions of the second hard mask sublayer 28. During this etch, the imprint material 32 serves as a mask that substantially prevents etching of the portions of the second hard mask sublayer 28 that is directly under the imprint material 32. The result of this etch, according to an example implementation, is illustrated in FIG. 5 and shows that the exposed portions of the second hard mask sublayer 28 are selectively etched away. Portions of the hard mask sublayer 28 that are directly under the imprint material (e.g., the resist) 32 remain. In some instances, this etch can be achieved by using an ICP.

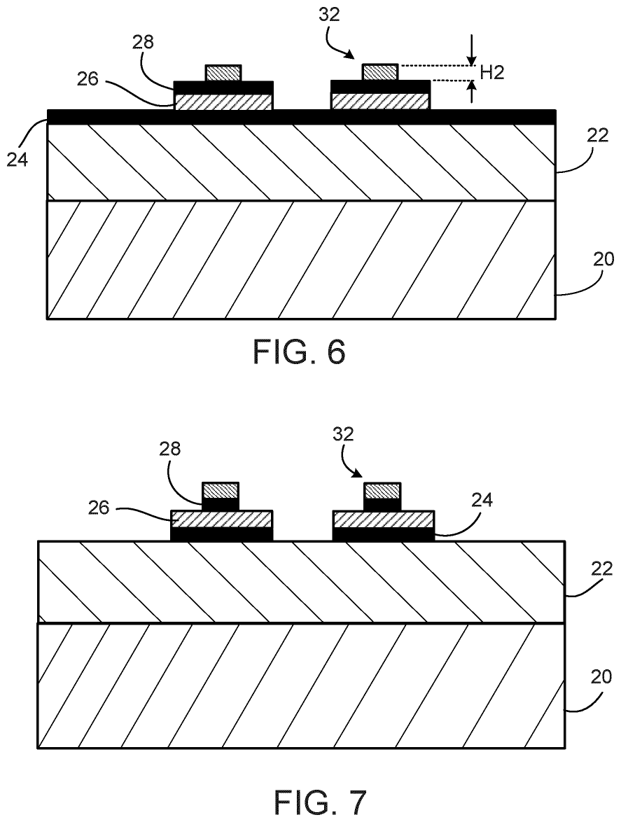

A third etch then is performed to remove exposed portions of the spacer sublayer 26 and reduce the height of the remaining imprint layer 32. During this etch, the second hard mask sublayer 28 serves as a mask that substantially prevents etching of the spacer (e.g., SiO₂) sublayer 26 that is directly under second hard mask sublayer 28. The result of this etch, according to an example implementation, is illustrated in FIG. 6 and shows that the exposed portions of the spacer (e.g., SiO₂) sublayer 26 are selectively etched away. Also, the height (H2) of the second level (L2) is reduced by this third etch to about 40 nm in this example. That is, in the illustrated example, the height of the imprint layer 32 is reduced by about 50±5 nm during this third etch. In some instances, this etch can be achieved by using an ICP.

A fourth etch then is performed to remove the exposed portions of the first hard mask sublayer 24. During this etch, the spacer (e.g., SiO₂) sublayer 26 serves as a mask that substantially prevents etching of the portions of the first hard mask sublayer 24 that are directly under the spacer sublayer 26. The result of this etch, according to an example implementation, is illustrated in FIG. 7 and shows that the exposed portions of the first hard mask sublayer 24 are selectively etched away. Portions of the first hard mask sublayer 24 that are directly under the spacer (e.g., SiO₂) sublayer 26 remain. Also, during this fourth etch, the exposed portions of the second hard mask sublayer 28 are selectively etched away, as shown in FIG. 7. The imprint material 32, however, serves as a mask that substantially prevents etching of the second hard mask sublayer 28 that is directly under the imprint material 32. In some instances, this etch can be achieved by using an ICP.

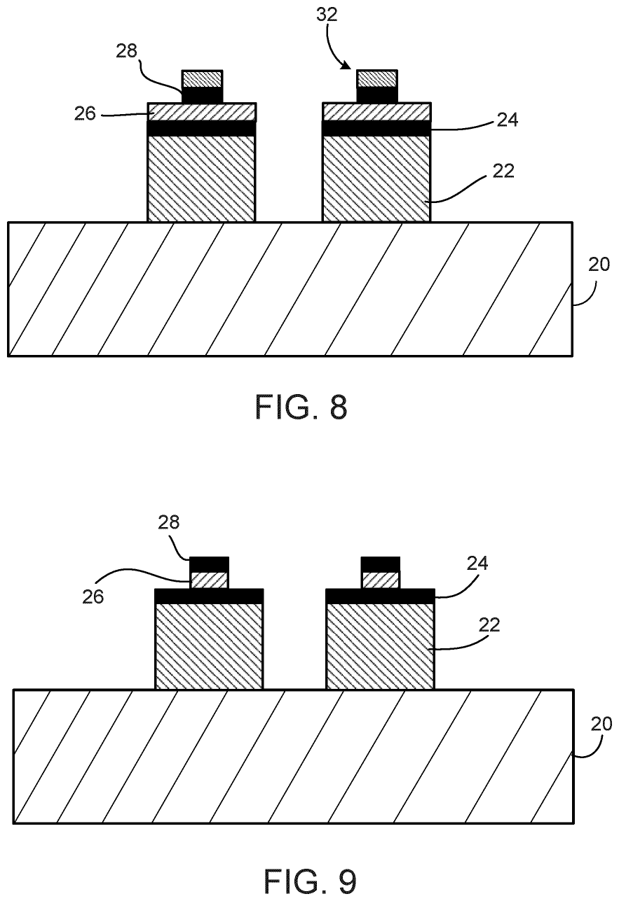

A fifth etch then is performed to remove, at least partially, the exposed portions of the optical (e.g., amorphous silicon) sublayer 22. During this etch, the spacer sublayer (e.g., SiO₂) 26 and/or the first hard mask sublayer 24 serve as a mask to substantially prevent etching of the portions of the optical sublayer 22 that are directly under those sublayers. The result of this etch, according to an example implementation, is illustrated in FIG. 8 and shows that the exposed portions of the optical (e.g., amorphous silicon) sublayer 22 are selectively etched away. In some implementations, the fifth etch is performed until the surface of the support 20 is exposed. In other implementations, it may be desirable to stop the fifth etch while some of the exposed optical sublayer 22 remains. In some instances, this etch can be achieved using an ICP.

A sixth etch then is performed to remove the remainder of the imprint layer (e.g., the resist) 32 as well as the exposed portions of the spacer (e.g., SiO₂) sublayer 26. During this etch, the second hard mask sublayer 28 serves as a mask to substantially prevent etching of the portions of the spacer (e.g., SiO₂) sublayer 26 that are directly under those sublayers. The result of this etch, according to an example implementation, is illustrated in FIG. 9 and shows that the exposed portions of the spacer (e.g., SiO₂) sublayer 26, as well as the remainder of the imprint layer 32, are selectively etched away. In some instances, this sixth etch can be achieved using an ICP.

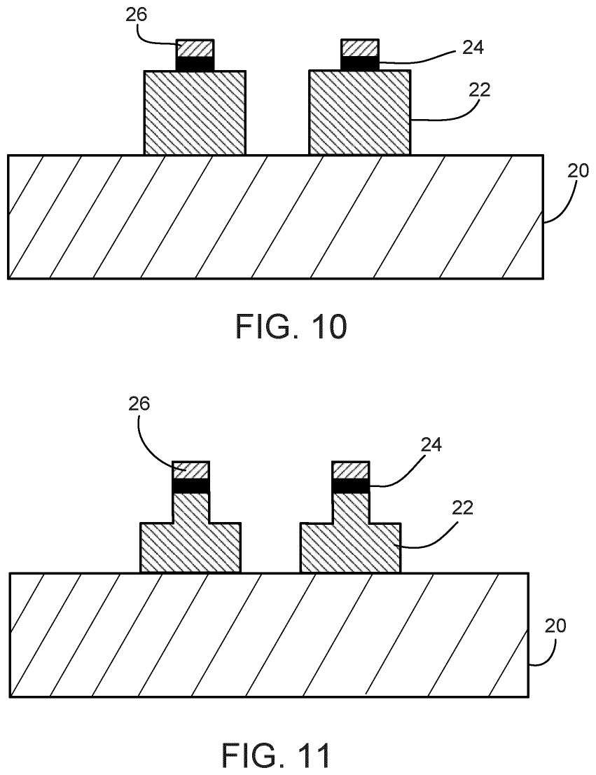

A seventh etch then is performed to remove the remainder of the second hard mask sublayer 28 and the exposed portions of the first hard mask sublayer 24. The spacer (e.g., SiO₂) sublayer 26 serves as a mask to substantially prevent etching of the portions of the first hard mask sublayer 24 that are directly under the spacer sublayer. The result of this etch, according to an example implementation, is illustrated in FIG. 10 and shows that the remainder of the second hard mask sublayer 28 and the exposed portions of the first hard mask sublayer 24 are selectively etched away. In some instances, this etch can be achieved using an ICP.

An eighth etch then is performed to remove the exposed portions of the optical (e.g., amorphous silicon) sublayer 22. The spacer (e.g., SiO₂) sublayer 26 and the first hard mask sublayer 24 serve as a mask to substantially prevent etching of the portions of the optical (e.g., amorphous silicon) sublayer 22 that are directly under those sublayers. The result of this etch, according to an example implementation, is illustrated in FIG. 11 and shows that the exposed portions of the optical (e.g., amorphous silicon) sublayer 22 are selectively etched away. In some instances, this etch can be achieved using an ICP. In some cases, it may be desirable to monitor the etch depth using atomic force microscopy (AFM).

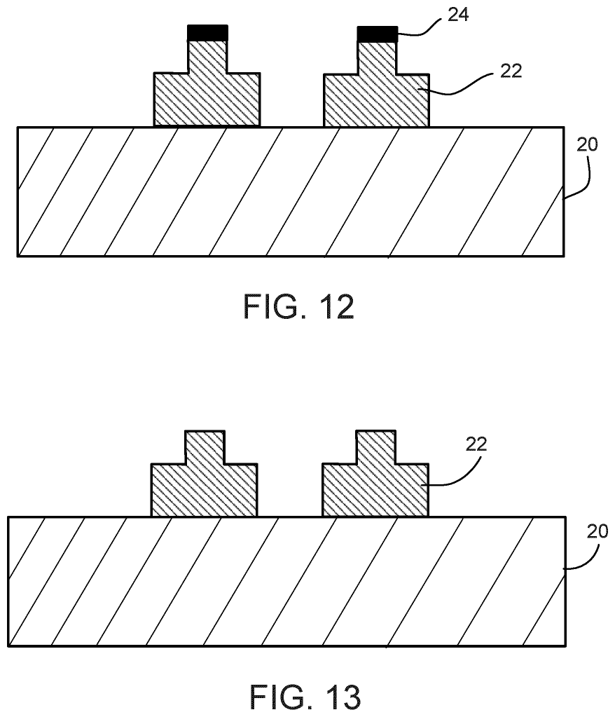

A ninth etch then is performed to remove the remainder of the spacer (e.g., SiO₂) sublayer 26. The result of this etch, according to an example implementation, is illustrated in FIG. 12 and shows that remainder of the spacer sublayer 26 is selectively etched away. In some instances, this etch can be achieved using an ICP.

A tenth etch then is performed to remove the remainder of the first hard mask sublayer 24. The result of this etch, according to an example implementation, is illustrated in FIG. 13 and shows that remainder of the first hard mask sublayer 24 is selectively etched away. In some instances, this etch can be achieved using an ICP. A comparison of FIG. 13 to FIG. 2 illustrates that the multi-level structure that was imprinted into the imprint layer (e.g., the resist) 32 has been transferred, as a result of the sequential etching operations, to the optical (e.g., amorphous silicon) sublayer 22. As noted above, the foregoing techniques can, in some instances, allow the lateral dimensions of the multi-level structure to be transferred to the optical sublayer 22 with only a little, if any, change in those dimensions.

In some implementations, a cleaning operation is performed prior to dicing of optical elements and later characterizing the optical properties. In some implementations, the cleaning operation includes using a piranha solution of sulfuric acid (98%) and hydrogen peroxide (30%) in a ratio 4:1 for about ten minutes, followed by a water rinse for about 8 minutes. The substrate(s) then can be dried, for example, in a barrel dryer. Different or additional cleaning techniques can be used in some implementations.

The optical properties of the resulting optical elements then can be determined using, for example, known techniques. The glass or other support 20 then can be separated, for example by dicing, into individual optical elements (e.g., DOEs or MOEs), each of which includes a multi-level structure defined by at least three different levels. Depending on the materials of the multi-level structure, the optical element may be configured to be operable for use, e.g., with infra-red (IR) or visible radiation. The depths and positions of the various levels with respect to one other can be configured according to a predefined optical function.

In some implementations, an optical element having a multi-level structure as described above can be integrated into modules that house one or more optoelectronic devices (e.g., light emitting and/or light sensing devices). The optical element can be used to modify or redirect an emitted or incoming light wave as it passes through the optical element.

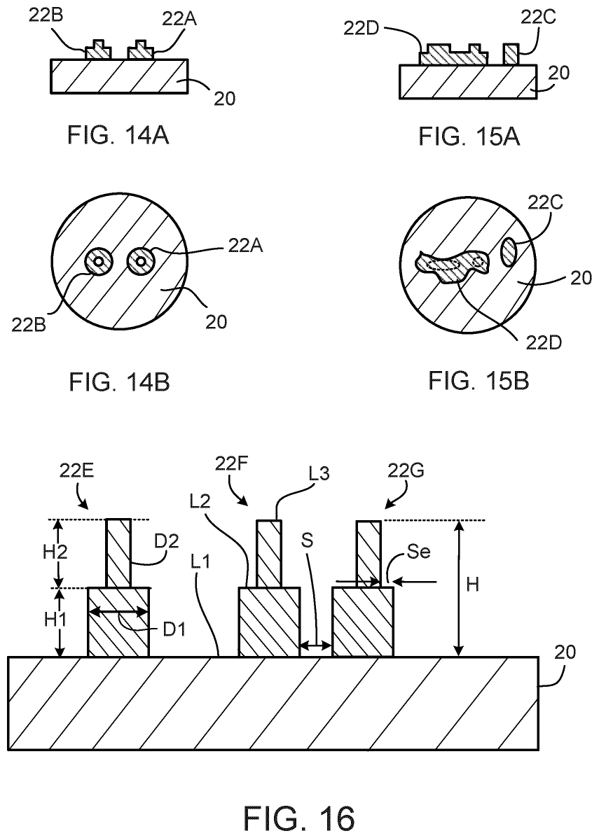

The foregoing techniques can facilitate manufacture of optical elements having multi-level structures whose features, in a top view (i.e., viewed perpendicular to the surface of the substrate 20), are circular, oval, square, rectangular, or some other shape. For example, FIGS. 14A-14B illustrate examples of features 22A, 22B that are circular. Likewise, FIGS. 15A-15B illustrate an example of a feature 22C having an oval shape. Further, in some implementations, one or more of the features, in a top view, can have a free-form shape. An example is shown in FIGS. 15A-15B, which include a feature 22D having a free-form shape.

FIG. 16 illustrates an example of a glass support 20 on which several multi-level optical elements 22E, 22F, 22G are disposed. The multi-level structure of FIG. 16 can be obtained, for example, using the techniques described above. In the illustrated example, the optical structure has three different levels L1, L2, L3. In some implementations, the optical elements 22E, 22F, 22G may have features with dimensions as follows. For example, in some instances, as shown in FIG. 16, each of the heights H1, H2 is in the range of 50 nm-3000 nm, and the total height H=H1+H2 is in the range of 100 nm-6000 nm. In some instances, the diameter D2 may be as small as 30 nm-50 nm. The diameter D1 can be larger than D2, and the edge spacing Se between levels L2 and L3 is at least 20 nm-70 nm. The smallest spacing S between adjacent optical elements is 30 nm-100 nm. Different values (i.e., smaller or larger) for the foregoing dimensions may be used in some implementations.

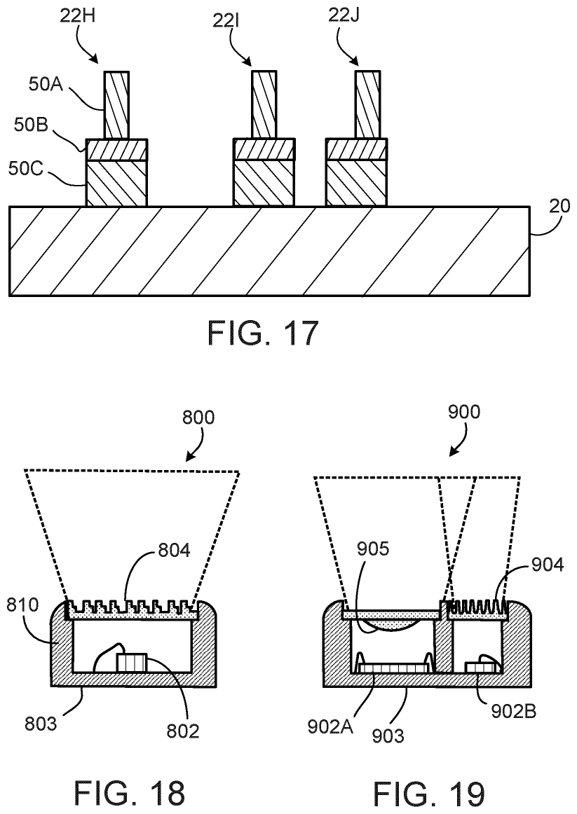

In some implementations, one of or more levels of the optical structure may be composed of more than one material. Likewise, the different levels of the optical structure may be composed of different materials from one another. For example, as shown in FIG. 17, each of the optical elements 22H, 22I, 22J has an upper level of the structure composed of a first material 50A, whereas the lower level of the structure is composed of second and third materials 50B, 50C one atop the other. Each of the materials 50A, 50B, 50C can be, for example, a different optical material that has a relatively high index of refraction (e.g., amorphous silicon, silicon nitride, titanium oxide, aluminum zinc oxide, a niobium oxide (e.g., NbO, NbO₂ or Nb₂O₅), zinc oxide, or a transparent conductor material). The materials can be selected, for example, based on their optical and other properties to provide particular optical functions at a given wavelength or range of wavelengths (e.g., a wavelength or range of wavelengths in the infra-red or visible portions of the spectrum).

Optical elements having a multi-level structures as described above can be integrated, for example, into a light sensing or light emitting module. For example, as shown in FIG. 18, a light sensing module (for example, an ambient light sensor module) 800 includes an active optoelectronic device 802 mounted on a substrate 803. The optoelectronic device 802 can be, for example, a light sensor (e.g., a photodiode, a pixel, or an image sensor) or a light emitter (e.g., a laser such as a vertical-cavity surface-emitting laser, or a light emitting diode). The module housing may include, for example, spacers 810 separating the optoelectronic device 802 and/or the substrate 803 from an optical element 804 having a multi-level structure as described above.

In the single-channel module of FIG. 18, the optical element 804 can be disposed so as to intersect a path of incoming light or to intersect a path of outgoing light. The optical element can be aligned with the active optoelectronic component 802 and can be mounted to the housing. In some cases (e.g., where the optoelectronic component is a light sensor), light incident on the module 800 is modified or redirected by the optical element 804. For example, in some cases, the optical element 804 modifies one or more characteristics of the light impinging on the optical element before the light is received and sensed by the optoelectronic component 802. In some instances, for example, the optical element 804 may focus patterned light onto the optoelectronic component 802. In some instances, the optical element 804 may split, diffuse and/or polarize the light before it is received and sensed by the optoelectronic component 802.

In some cases (e.g., where the optoelectronic component 802 is a light emitter), light generated by the optoelectronic component 802 passes through the optical element 804 and out of the module. In the single-channel module of FIG. 18, the optical element 804 can be disposed so as to intersect a path of the outgoing light 806. The optical element 804 can modify or redirect the light. For example, in some cases, one or more characteristics of the light impinging on the optical element are modified before the light exits the module 800. In some cases, the module 800 is operable to produce, for example, one or more of structured light, diffused light, or patterned light.

One or more optical elements having multi-level structures as described also can be integrated into multi-channel modules. As shown in FIG. 19, such a multi-channel module 900 can include, for example, a light sensor 902A and a light emitter 902B, both of which can be mounted on the same printed circuit board (PCB) or other substrate 903. In the illustrated example, an optical element 904 having a multi-level structure as described above is mounted to the housing over the light emitter 902B. The multi-channel module can include a light emission channel and a light detection channel, which may be optically isolated from one another by a wall that forms part of the module housing. A lens 905 may be provided over the light sensor 902A.

In some instances, one or more of the modules described above may be integrated, for example, into mobile phones, laptops, televisions, wearable devices, or automotive vehicles.

While this document contains many specific implementation details, these should not be construed as limitations on the scope of any inventions or of what may be claimed, but rather as descriptions of features specific to particular embodiments. Certain features that are described in this document in the context of separate embodiments can also can be implemented in combination in a single embodiment. Conversely, various features that are described in the context of a single embodiment can also can be implemented in multiple embodiments separately or in any suitable sub-combination. Various modifications can be made to the foregoing examples. Accordingly, other implementations also are within the scope of the claims.

1. A method comprising:
imprinting a multi-level structured surface of a tool into an imprint material that is disposed on a substrate so that the imprint material is imprinted with a multi-level structure corresponding to the multi-level structured surface of the tool, wherein the substrate includes a plurality of sublayers disposed on a support, wherein the plurality of sublayers are disposed one atop another and include an optical sublayer on the support, a first hard mask sublayer on the optical sublayer, a spacer sublayer on the first hard mask sublayer, and a second hard mask sublayer on the spacer sublayer; and
subsequently performing a plurality of etching operations to cause the imprinted multi-level structure to be transferred into the optical sublayer of the substrate.

2. The method of claim 1 wherein the optical sublayer is composed of amorphous, poly-crystalline, or crystalline silicon.

3. The method of claim 1 wherein the optical sublayer is composed of silicon nitride titanium oxide, zinc oxide, silicon carbide, aluminum zinc oxide, a niobium oxide, or gallium nitride.

4. The method of claim 1, wherein each of the hard mask sublayers is composed of a metal.

5. The method of claim 3 wherein at least one of the hard mask sublayers is composed of chrome.

6. The method of claim 3 wherein at least one the hard mask sublayers is composed of aluminum or titanium.

7. The method of claim 1, wherein the spacer sublayer is composed of silicon dioxide or silicon nitride.

8. The method of claim 1, wherein each of the plurality of etching operations is a selective etch.

9. The method of claim 1, wherein the imprint material comprises a resist.

10. The method of claim 1 wherein the optical sublayer is composed of silicon, each of the first and second hard mask sublayers is composed of chrome, the spacer sublayer is composed of silicon dioxide, and the imprint material is a resist.

11. The method of claim 1 wherein performing a plurality of etching operations includes performing the following etches sequentially:
a first etch to remove a residual layer of the imprint material;
a second etch to remove exposed portions of the second hard mask sublayer;
a third etch to remove exposed portions of the spacer sublayer;
a fourth etch to remove exposed portions of the first hard mask sublayer;
a fifth etch to remove, at least partially, exposed portions of the optical sublayer;
a sixth etch to remove a remainder of the imprint material and exposed portions of the spacer sublayer;
a seventh etch to remove a remainder of the second hard mask sublayer and exposed portions of the first hard mask sublayer;
an eighth etch to remove exposed portions of the optical sublayer;
a ninth etch to remove a remainder of the spacer sublayer; and
a tenth etch to remove a remainder of the first hard mask sublayer.

12. The method of claim 11 wherein the third etch also reduces a height of the imprint material.

13. The method of claim 1, wherein at least one of the plurality of etch operations is an inductively coupled plasma (ICP) etch.

14. The method of claim 1, wherein the multi-level structured surface of the tool is imprinted into the imprint material by nanoimprint lithography.

15. The method of claim 1, wherein the multi-level structured surface of the tool corresponds to a pixel layout design for optical elements.

16. The method of claim 15 wherein the optical elements include at least one of diffractive optical elements of meta optical elements.

17. The method of claim 1, wherein the support is composed of glass.

18. The method of claim 1, wherein the multi-level structure imprinted into the imprint material and transferred into the optical sublayer of the substrate includes at least three different levels.
